(19) United States
(12) Patent Application Publication
(10) Pub. No.: US 2013/0106411 A1
(43) Pub. Date: May 2, 2013

(54) MAGNETOSTRICTIVE POSITION TRANSDUCER AND MAGNETOSTRICTIVE SENSING ELEMENT THEREOF

(71) Applicants: Wei-Wu Chen, New Taipei (TW); Teng-Jin You, New Taipei (TW); Chao-Kai Cheng, New Taipei (TW)

(72) Inventors: Wei-Wu Chen, New Taipei (TW); Teng-Jin You, New Taipei (TW); Chao-Kai Cheng, New Taipei (TW)

(73) Assignee: FINETEK CO., LTD, New Taipei (TW)

(21) Appl. No.: 13/282,189

(22) Filed: Oct. 26, 2011

(51) Int. Cl. G01R 33/02

(52) U.S. Cl. 324/252

(57) ABSTRACT

A magnetostrictive position transducer and a magnetostrictive sensing element thereof are characterized that a magnetostrictive sensing element is mounted inside an outer tube, the magnetostrictive sensing element has two end mounts respectively mounted on two ends of an insulating and hollow tube and a magnetostrictive wire mounted through the tube, the magnetostrictive wire has two wire adapters respectively mounted on two ends of the magnetostrictive wire and respectively mounted in the end mounts so that the magnetostrictive wire is contactlessly mounted through the tube, a sensing module is mounted in one of wire adapter to sense signal variation on the magnetostrictive wire. With the foregoing structure, the magnetostrictive sensing element does not require devices for applying pre-stress and damping, thereby simplifying structure and ensuring high stability in measurement of the magnetostrictive position transducer.

### BACKGROUND OF THE INVENTION

1. Field of the Invention

The present invention relates to a magnetostrictive position transducer and a magnetostrictive sensing element thereof, and more particularly to a magnetostrictive position transducer specially designed and structurally simplified to have a higher operational stability and having a detachable structure to facilitate mounting and dismounting.

2. Description of the Related Art

A magnetostrictive position transducer is basically composed of a magnetostrictive wire, at least one moving magnet, a current pulse generator and a strain pulse detector. Given a magnetic field variation resulting from a strain of one end of the magnetostrictive wire, the strain pulse detector can detect the magnetic field variation through a sensing coil at the other end of the magnetostrictive wire. Besides, strain of a piezoelectric material can be detected and converted into voltage. Such effect is called magnetostrictive effect. When combined with inverse magnetostriction, such effect is called inverse magnetostrictive effect and can detect a variation of a magnetostrictive wire serving as an output signal. The magnetostrictive position transducer is operated to detect a vibration signal of an echo signal using amount of magnetostriction. The entire operation includes the following steps.

(1) An electric trigger feeds a current pulse signal into a magnetostrictive wire to generate an excited magnetic field to axially propagate along the magnetostrictive wire in light speed.
(2) The excited magnetic field collides with a fixed magnetic field of the at least one moving magnet. As the mass of the magnetostrictive wire is far less than that of the moving magnetic, the reaction force arising from collision of the magnetic fields excites a sonic shock wave to propagate along the magnetostrictive wire and toward two ends of the magnetostrictive wire.
(3) When received, the shock wave is converted into a voltage pulse signal by a piezoelectric transducer or a sensing coil.
(4) Calculate a shock wave speed and a time difference using the current pulse signal and the voltage pulse signal to obtain a distance to a position.

As the magnetostrictive position transducer is an industrial position sensor with substantial precision and stability, the structural design thereof should be reliable and the assembly should be as simple as possible.

As disclosed in U.S. Pat. No. 5,998,991, a magnetostrictive position transducer 40 has an inner tube 44, an outer tube 54 and a magnetostrictive wire 12 mounted in the inner tube 44. The magnetostrictive wire 12 is fixed on two ends of the inner tube 44 through a spring 18 so that the spring 18 exerts a pre-stress on the magnetostrictive wire 12. A first end of the magnetostrictive wire 12 is connected with a damper 20. Furthermore, the first end of the magnetostrictive wire 12 is connected with an external connector 58, and a second end is connected with another connector 60 through the inner tube 44 so as to connect to an external sensing circuit. The inner tube 4 is made of a conductive material. To prevent shock wave attenuation caused by the contact between the magnetostrictive wire 12 and an inside wall of the inner tube 44 from affecting the pulse signal transmission, multiple spaced spacers 42 are mounted inside the inner tube 44 to ensure that the inner tube 44 and the magnetostrictive wire 12 are fully isolated.

The spring 18 in the conventional magnetostrictive position transducer serves to exert a pre-stress to both ends of the magnetostrictive wire 12 so that the magnetostrictive wire 12 can be subjected to a tensile force to maintain good electromgnetic signal and linearity in measurement. However, lengthy operation duration and high-temperature environment make the spring 18 prone to elastic fatigue. As the spring is a critical element in the conventional magnetostrictive position transducer, the elastic fatigue leads to unstable linearity in measurement. Also, the presence of the spring adds complication in parts assembly.

Furthermore, the damper 20 mounted on the magnetostrictive wire 12 to prevent the interference arising from torsional wave returned along the magnetostrictive wire 12. If the interference can be removed, the damper 20 is certainly an optional element in design. As the magnetostrictive position transducer 40 is grounded or transmits signal with the inner tube 44, mounting the spacers 42 in the inner tube to ensure that the magnetostrictive wire 12 is not in contact with the inner tube 44 is also a complicated assembling process.

### SUMMARY OF THE INVENTION

A first objective of the present invention is to provide a magnetostrictive sensing element of a magnetostrictive position transducer requiring no pre-stress application or no spring, simplifying a damper design for magnetostrictive wire without trading off internal structural robustness, and employing assembly of multiple insulating and non-conductive combination tubes to prevent shock wave attenuation occurring between the magnetostrictive wire and an inner wall of each of the combination tubes and maintaining signal transmission capability.

To achieve the foregoing objective, the magnetostrictive sensing element has a tube, a first end mount, a second end mount, a sensing module and a magnetostrictive wire.

The tube is hollow and has an inner diameter, a first end and a second end.

The first end mount is mounted around the first end of the tube, is hollow, and has an inner end and an outer end. The inner end has a first wire slot formed therein to communicate with the tube. The outer end has a first mounting slot formed therein to communicate with the first wire slot.

The second end mount is mounted around the second end of the tube, is hollow, and has an inner end and an outer end. The inner end has a second wire slot formed therein to communicate with the tube. The outer end has a second mounting slot formed therein to communicate with the second wire slot.

The sensing module is mounted inside the first mounting slot of the first end of the first end mount.

The magnetostrictive wire is mounted through the tube, has a wire diameter smaller than the inner diameter of the tube, and has two wire adapters respectively mounted on two ends of the magnetostrictive wire. One wire adapter is mounted in the first mounting slot of the first end mount and is mounted through the sensing module. The other wire adapter is mounted in the second mounting slot of the second end mount. The two ends of the magnetostrictive wire are respectively fixed on the first end and the second end of the tube by using the two wire adapters so that the magnetostrictive wire is contactlessly mounted through the tube.

With the foregoing structure, the magnetostrictive wire is fixed in the first end mount and second end mount at the first end and second end of the tube by using the wire adapters, thereby requiring no spring and effectively simplify the structure and assembling process.

Moreover, the tube can be assembled with multiple combination tubes and couplers. As the combination tubes and the couplers are both insulating, they are immune to generation of interference to the magnetostrictive wire. Additionally, since each coupler has an inner diameter smaller than that of each of the combination tubes, the magnetostrictive wire is limited not to contact the inner walls of the combination tubes, thereby eliminating generation of shock wave attenuation and maintaining signal transmission capability.

A second objective of the present invention is to provide a magnetostrictive position transducer facilitating assembly and disassembly thereof.

To achieve the foregoing objective, the magnetostrictive position transducer has a main body, a magnetostrictive sensing element, a sensing circuit module, an outer tube and at least one moving magnet.

The magnetostrictive sensing element is the same as the foregoing magnetostrictive sensing element. The tube is combined with one end of the main body.

The sensing circuit module is mounted in the main body and is electrically connected with the magnetostrictive sensing element.

The outer tube is detachably mounted around the tube of the magnetostrictive sensing element.

The at least one moving magnet is movably mounted around the outer tube. Each one of the at least one moving magnet has at least one permanent magnet mounted therein.

The foregoing structure allows the outer tube and the at least one moving magnet to be detachable, thereby facilitating mounting, maintenance and the need of frequent assembly and disassembly.

Other objectives, advantages and novel features of the invention will become more apparent from the following detailed description when taken in conjunction with the accompanying drawings.

### BRIEF DESCRIPTION OF THE DRAWINGS

FIG. 1 is a side view in partial division of an embodiment of a magnetostrictive position transducer in accordance with the present invention;

FIG. 2 is a side view in partial division of a magnetostrictive sensing element of the magnetostrictive position transducer in FIG. 1;

FIG. 3 is a cross-sectional view of the magnetostrictive sensing element in FIG. 2;

FIG. 4 is an enlarged side view in partial division of the magnetostrictive sensing element in FIG. 2;

FIG. 5 is another enlarged side view in partial division of the magnetostrictive sensing element in FIG. 2;

FIG. 6 is another cross-sectional view of the magnetostrictive sensing element in FIG. 2; and

FIG. 7 is a side view of another embodiment of a magnetostrictive position transducer in accordance with the present invention.

### DETAILED DESCRIPTION OF THE INVENTION

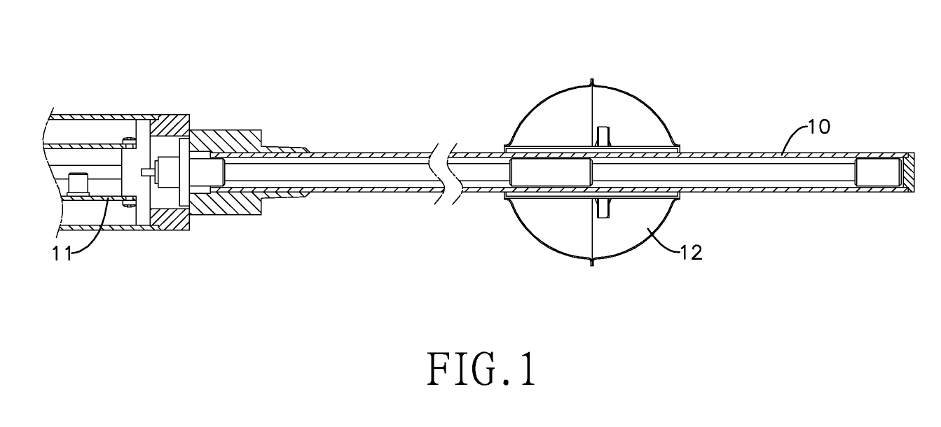

With reference to FIG. 1, an embodiment of a magnetostrictive position transducer in accordance with the present invention has an outer tube 10, a magnetostrictive sensing element, a sensing circuit module 11 and a moving magnet 12. The magnetostrictive sensing element is mounted inside the outer tube 10. The sensing circuit module 11 is electrically connected with the magnetostrictive sensing element. The moving magnet 12 is movably mounted around the outer tube 10, slidably aligns with the magnetostrictive sensing element and has a permanent magnet mounted inside the moving magnet 12. When the moving magnet 12 moves up and down with a liquid level, the permanent magnet induces the magnetostrictive sensing element inside the outer tube 10. The magnetic induction is detected by the sensing circuit module 11. The major characteristic of the present invention lies in the magnetostrictive sensing element inside the outer tube 10. A specific structure of the magnetostrictive sensing element is further introduced in the following.

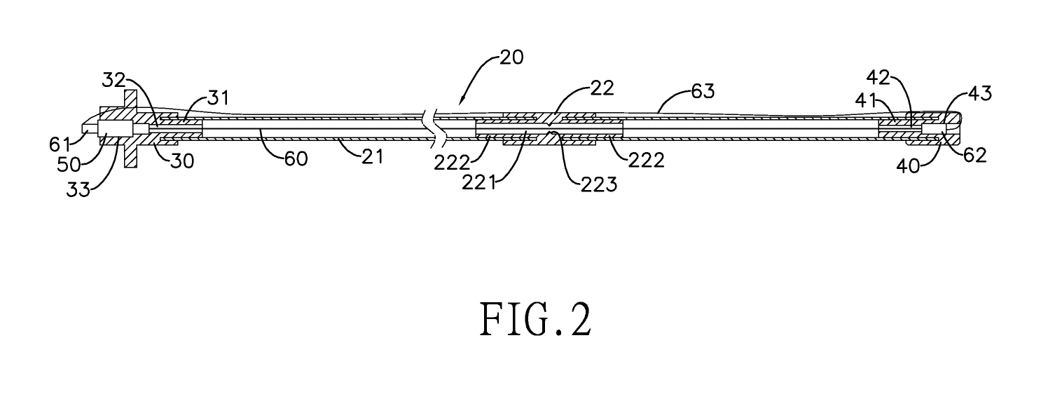

With reference to FIG. 2, the magnetostrictive sensing element has a tube 20, a first end mount 30, a second end mount 40, a sensing module 50 and a magnetostrictive wire 60.

The tube is hollow and has a first end and a second end. The first end is on the left and the second end is on the right in FIG. 2. The tube 20 may be a single tube or assembled with multiple combination tubes. In the present embodiment, the tube 20 is assembled with multiple combination tubes 21, and a hollow coupler 22 is mounted around each two adjacent combination tubes 21. To facilitate understanding of detailed structure and connection relationship with minimum combination tubes 21 and the hollow couplers 22, the tube 20 is illustrated by combining two combination tubes 21 and a hollow coupler 22. The combination tubes 21 and the hollow couplers 22 are made from an insulating material or surface treated to be insulating. The insulating material may be a polymer.

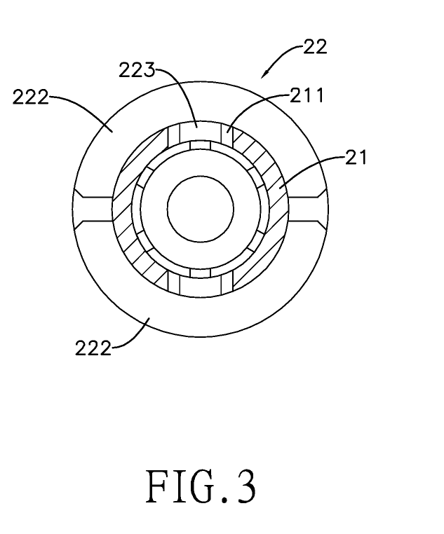

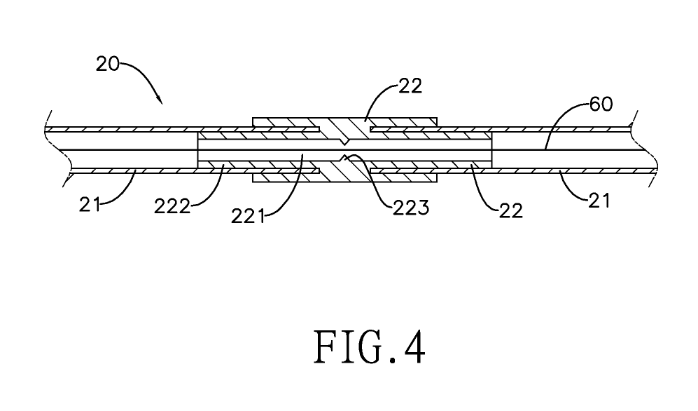

Each combination tube 21 has an inner diameter and has two open ends to communicate with each other for the corresponding hollow couplers 22 to be mounted therearound, and for the corresponding first end mount 30 and second end mount 40 to be mounted therein. In the present embodiment, the hollow coupler 22 is tubular and has a through hole 221 centrally formed through the hollow coupler 22 for the magnetostrictive wire 60 to pass through. The hollow coupler 22 has two coupling portions 222. Each coupling portion 222 is formed on one end of the hollow coupler 22 and has a reduced outer diameter matching the inner diameter of the combination tube 21 so as to facilitate coupling. With reference to FIG. 3, besides a tight fit, the coupling portion 222 of the hollow coupler 22 engages a combination tube 21 by an engagement structure having two teeth 223 oppositely formed on and protruding from two inner walls of the two coupling portions 222 and two tooth spaces 211 formed through the combination tube 21 and engaging the respective teeth 223 so as to prevent the magnetostrictive wire 60 from being rotated due to the rotation of each combination tube 21. As the diameter of the through hole 221 of each hollow coupler 22 is smaller than the inner diameter of each combination tube 21, the magnetostrictive wire 60 passing through each hollow coupler 22 is limited by the hollow couplers 22 and is uneasy to be in touch with an inner wall of any combination tube 21. Hence, the shock wave attenuation can be avoided. With reference to FIG. 4, each hollow coupler 22 has an annular ridge 223 formed on and protruding radially and inwardly from an inner wall of the through hole of the hollow coupler 22 to further limit the magnetostrictive wire 60 having a wire diameter smaller than an inner diameter of the annular ridge 223 and prevent the magnetostrictive wire 60 from being in contact with the inner wall of the combination tube 21.

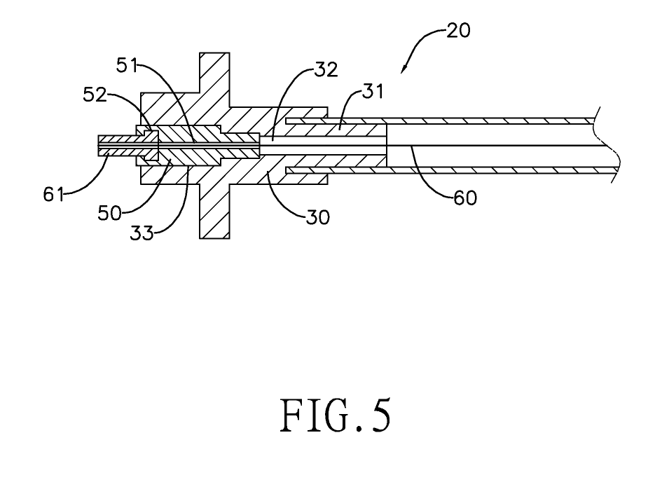

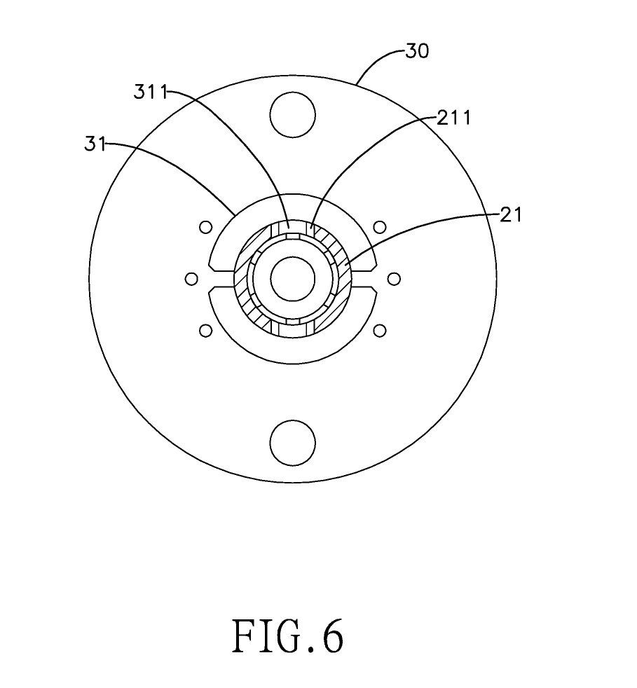

With reference to FIGS. 2 and 5, the first end mount 30 is mounted around the first end of the tube 20, is hollow, and has an inner end and an outer end. The inner end has an insertion portion 31 formed thereon and having a reduced outer diameter. The outer diameter of the insertion portion 31 matches the inner diameter of the combination tubes 21 of the tube 20 so as to facilitate fitting the insertion portion 31 in a corresponding combination tube 21. Similarly, with reference to FIG. 6, the insertion portion 31 of the inner end of the first end mount 30 engages a corresponding combination tube 21 by an engagement mechanism having two teeth 311 oppositely formed on and protruding from an inner wall of the insertion portions 31 and two tooth spaces 211 oppositely formed through the combination tube 21 and engaging the respective teeth 311.

The first end mount 30 further has a wire slot 32 and a mounting slot 33. The wire slot 32 is formed in the inner end of the first end mount 30 to communicate with the tube 20. The mounting slot 33 is formed in the outer end of the first end mount 30 to communicate with the wire slot 32 and serves for mounting the sensing module 50 therein. The sensing module 50 has an insulating and cylindrical body and a sensing coil (not shown) mounted inside the body. An outer diameter of the body matches an inner diameter of the mounting slot 33 to facilitate the body to be mounted inside the mounting slot 33. With further reference to FIG. 5, the cylindrical body of the sensing module 50 has a through hole 51 formed through two ends of the body for the magnetostrictive wire 60 to pass therethrough. The through hole 51 has an adapter slot 52 formed at an outer end thereof and having an expanded inner diameter for a first wire adapter 61 formed on one end of the magnetostrictive wire 60 to be mounted in the adapter slot 52. The sensing module 50 may be a piezoelectric material, an electromechanical transducer, an induction coil or a combination of the aforementioned elements.

With further reference to FIG. 2, the second end mount 40 is mounted around the second end of the tube 20, is structurally similar to the first end mounted 30 in having a hollow form, and has an outer end and an inner end. The inner end has an insertion portion 41 formed thereon and having a reduced outer diameter. The outer diameter of the insertion portion 41 matches the inner diameter of the combination tubes 21 of the tube 20 to facilitate fitting the insertion portion 41 in a corresponding combination tube 21. Similarly, the insertion portion 41 of the inner end of the second end mount 40 engages a corresponding combination tube 21 by an engagement mechanism identical to that between the insertion portion 31 of the inner end of the first end mount 30 and the combination tube 21. The second end mount 40 further has a wire slot 42 and a mounting slot 43. The wire slot 42 is formed in the inner end of the second end mount 40 to communicate with the tube 20 for the magnetostrictive wire 60 to pass therethrough. The mounting slot 43 is formed in the outer end of the second end mount 40 to communicate with the wire slot 42 and serves for mounting a second wire adapter 62 formed on the other end of the magnetostrictive wire 60 in the mounting slot 43. The magnetostrictive wire 60 is pulled out through the second wire adapter 62, is extended to the first end mount 30 through a return signal line 63 along a periphery of the tube 20, and is soldered in the first end mount 30.

As mentioned, the magnetostrictive wire 60 penetrates through the combination tubes 21 and the hollow couplers 22 of the tube 20, and has a first wire adapter 61 and the second wire adapter 62 respectively and securely mounted in both ends of the tube 20. The first wire adapter 61 is mounted in the mounting slot 33 of the first end mount 30 and is securely mounted in the adapter slot 52 of the sensing module 50. The second wire adapter 62 is mounted in the mounting slot 43 of the second end mount 40. The first wire adapter 61 and the second wire adapter 62 serve to tighten both ends of the magnetostrictive wire 60 and respectively fix both ends of the magnetostrictive wire 60 on the first end and the second end of the tube 20. Accordingly, the magnetostrictive wire 60 can be mounted through the tube 20 without contacting the inner wall of the tube 20. The magnetostrictive wire 60 may be made of an enameled wire.

The magnetostrictive wire 60 in the present invention is fixed in the first end and the second end of the tube 20 by using the first wire adapter 61 and the second wire adapter 62. As a result, the magnetostrictive wire 60 can be contactlessly and firmly mounted inside the tube 20 without using a spring, thereby effectively simplifying the structure and assembling procedures of the present invention. Additionally, if the tube 20 is assembled with the combination tubes 21, which are connected with the hollow couplers 22, the hollow couplers 22 have the inner diameter smaller than that of the tube 20, thereby further limiting the magnetostrictive wire 60 to contact with the inner wall of the tube 20, prevent the generation of shock wave attenuation, and maintain signal transmission capability. The annular ridge 221 formed on the inner wall of the through hole 221 of the hollow coupler 22 can further securely isolate the magnetostrictive wire 60 from the inner walls of the combination tubes 21.

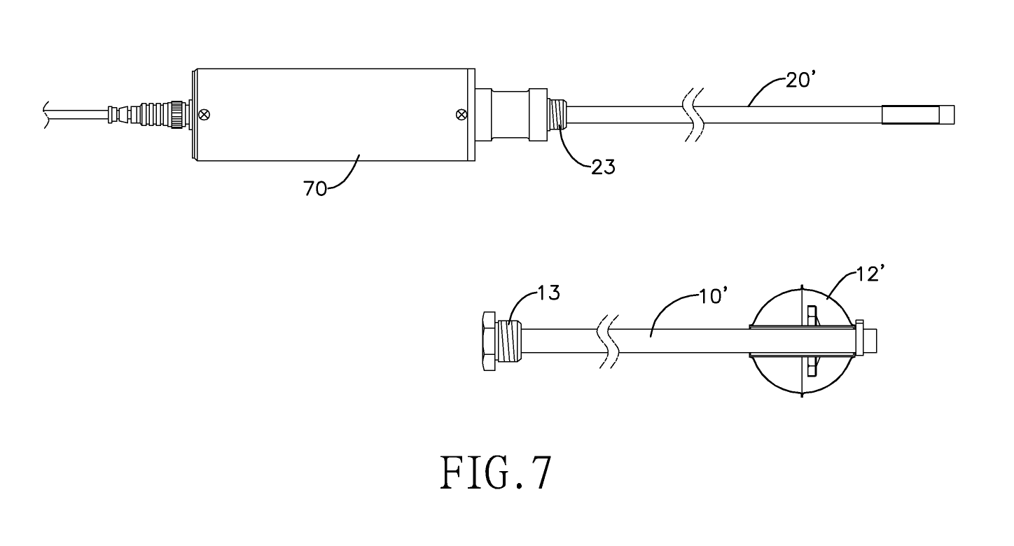

With reference to FIG. 7, another embodiment of a magnetostrictive position transducer in accordance with the present invention is shown. The magnetostrictive position transducer is characterized in that the magnetostrictive sensing element employs a mechanical means to be combined with a main body 70. The mechanical means may be a fastener, a sliding block, a sliding channel, screwing means, welding means and the like. The magnetostrictive position transducer has a sensing circuit module (not shown) mounted in the main body 70 and electrically connected with the magnetostrictive sensing element. In the present embodiment, the tube 20′ of the magnetostrictive sensing element has a threaded connector 23 formed on one end thereof adjacent to the main body 70 to serve to be mounted in the outer tube 10′. To be screwed with the tube 20′, the outer tube 10′ has a threaded connector 13 to facilitate mounting of the tube 20′ around the outer tube 10′ by screwing the threaded connectors 13, 23 together. Moreover, at least one moving magnet 12′ can be movably mounted around the outer tube 10′, and each one of the at least one moving magnet 12′ has at least one permanent magnet mounted therein.

In sum, with the aforementioned structure of the present invention, the present invention can provide the magnetostrictive position transducer with more simplified structure and more stability in measurement.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A magnetostrictive sensing element of a magnetostrictive position transducer, comprising:
a tube being hollow and having an inner diameter, a first end and a second end;
a first end mount mounted around the first end of the tube, being hollow, and having:
an inner end having a first wire slot formed therein to communicate with the tube; and
an outer end having a first mounting slot formed therein to communicate with the first wire slot;
a second end mount mounted around the second end of the tube, being hollow, and having:
an inner end having a second wire slot formed therein to communicate with the tube; and
an outer end having a second mounting slot formed therein to communicate with the second wire slot;
a sensing module mounted inside the first mounting slot of the first end of the first end mount; and
a magnetostrictive wire mounted through the tube, having a wire diameter smaller than the inner diameter of the tube, and having two wire adapters respectively mounted on two ends of the magnetostrictive wire, wherein one wire adapter is mounted in the first mounting slot of the first end mount and mounted through the sensing module, the other wire adapter is mounted in the second mounting slot of the second end mount, and the two ends of the magnetostrictive wire are respectively fixed on the first end and the second end of the tube by using the two wire adapters so that the magnetostrictive wire is contactlessly mounted through the tube.

2. The magnetostrictive sensing element as claimed in claim 1, wherein
the tube is assembled with multiple combination tubes;
a hollow coupler is mounted around each two adjacent combination tubes;
each combination tube has an inner diameter; and
the hollow coupler is tubular, and has:
a through hole centrally formed through the hollow coupler for the magnetostrictive wire to pass through; and
two coupling portions, each coupling portion formed on one end of the hollow coupler and having a reduced outer diameter matching the inner diameter of each combination tube.

3. The magnetostrictive sensing element as claimed in claim 2, wherein each hollow coupler has an annular ridge formed on and protruding radially and inwardly from an inner wall of the through hole of the hollow coupler.

4. The magnetostrictive sensing element as claimed in claim 2, wherein the coupling portion of each hollow coupler engages a corresponding combination tube by a tight fit.

5. The magnetostrictive sensing element as claimed in claim 2, wherein the coupling portion of each hollow coupler engages a corresponding combination tube by an engagement mechanism formed on the inner wall of the coupling portion and formed through the combination tube to prevent mutual rotation of the hollow coupler and the combination tube.

6. The magnetostrictive sensing element as claimed in claim 2, wherein the inner end of each of the first end mount and the second end mount has an insertion portion formed thereon and having a reduced outer diameter matching the inner diameter of a corresponding combination tube of the tube.

7. The magnetostrictive sensing element as claimed in claim 6, wherein the insertion portion of the inner end of each of the first end mount and the second end mount engages a corresponding combination tube by an engagement mechanism formed on an inner wall of the insertion portion and formed through the combination tube to prevent mutual rotation of the combination tube and one of the first end mount and the second end mount.

8. The magnetostrictive sensing element as claimed in claim 7, wherein the sensing module has a cylindrical body, and an outer diameter of the cylindrical body matches an inner diameter of the mounting slot of the first end mount for the cylindrical body to be mounted inside the mounting slot.

9. The magnetostrictive sensing element as claimed in claim 8, wherein the sensing module has a cylindrical body having a through hole formed through two ends of the body for the magnetostrictive wire to pass therethrough, the through hole has an adapter slot formed at an outer end thereof and having an expanded inner diameter for one of the wire adapters formed on a corresponding end of the magnetostrictive wire to be mounted therein.

10. The magnetostrictive sensing element as claimed in claim 1, wherein the sensing module is one of a piezoelectric material, an electromechanical transducer, an induction coil and a combination of the piezoelectric material, the electromechanical transducer and the induction coil.

11. The magnetostrictive sensing element as claimed in claim 5, wherein the sensing module is one of a piezoelectric material, an electromechanical transducer, an induction coil and a combination of the piezoelectric material, the electromechanical transducer and the induction coil.

12. The magnetostrictive sensing element as claimed in claim 7, wherein the sensing module is one of a piezoelectric material, an electromechanical transducer, an induction coil and a combination of the piezoelectric material, the electromechanical transducer and the induction coil.

13. A magnetostrictive position transducer comprising:
a main body;
a magnetostrictive sensing element same as that claimed in claim 1, wherein the tube is combined with one end of the main body;
a sensing circuit module mounted in the main body and electrically connected with the magnetostrictive sensing element;
an outer tube detachably mounted around the tube of the magnetostrictive sensing element; and
at least one moving magnet movably mounted around the outer tube and slidably aligning with the magnetostrictive sensing element, each one of the at least one moving magnet having at least one permanent magnet mounted therein.

14. A magnetostrictive position transducer comprising:
a main body;
a magnetostrictive sensing element same as that claimed in claim 5, wherein the tube is combined with one end of the main body;
a sensing circuit module mounted in the main body and electrically connected with the magnetostrictive sensing element;
an outer tube detachably mounted around the tube of the magnetostrictive sensing element; and
at least one moving magnet movably mounted around the outer tube and slidably aligning with the magnetostrictive sensing element, each one of the at least one moving magnet having at least one permanent magnet mounted therein.

15. A magnetostrictive position transducer comprising:
a main body;
a magnetostrictive sensing element same as that claimed in claim 7, wherein the tube is combined with one end of the main body;
a sensing circuit module mounted in the main body and electrically connected with the magnetostrictive sensing element;
an outer tube detachably mounted around the tube of the magnetostrictive sensing element; and
at least one moving magnet movably mounted around the outer tube and slidably aligning with the magnetostrictive sensing element, each one of the at least one moving magnet having at least one permanent magnet mounted therein.

16. The magnetostrictive position transducer as claimed in claim 13, wherein the tube of the magnetostrictive sensing element is combined with the main body by using a mechanical means.

17. The magnetostrictive position transducer as claimed in claim 14, wherein the tube of the magnetostrictive sensing element is combined with the main body by using a mechanical means.

18. The magnetostrictive position transducer as claimed in claim 15, wherein the tube of the magnetostrictive sensing element is combined with the main body by using a mechanical means.

19. The magnetostrictive position transducer as claimed in claim 16, wherein the tube of the magnetostrictive sensing element has a threaded connector formed on one end thereof adjacent to the main body, the outer tube has a threaded connector to be screwed around the threaded connector of the tube.

20. The magnetostrictive position transducer as claimed in claim 17, wherein the tube of the magnetostrictive sensing element has a threaded connector formed on one end thereof adjacent to the main body, the outer tube has a threaded connector to be screwed around the threaded connector of the tube.

21. The magnetostrictive position transducer as claimed in claim 18, wherein the tube of the magnetostrictive sensing element has a threaded connector formed on one end thereof adjacent to the main body, the outer tube has a threaded connector to be screwed around the threaded connector of the tube.

22. The magnetostrictive position transducer as claimed in claim 16, wherein the mechanical means is one of a fastener, a sliding block, a sliding channel, a screwing means and a welding means.

23. The magnetostrictive position transducer as claimed in claim 17, wherein the mechanical means is one of a fastener, a sliding block, a sliding channel, a screwing means and a welding means.

24. The magnetostrictive position transducer as claimed in claim 18, wherein the mechanical means is one of a fastener, a sliding block, a sliding channel, a screwing means and a welding means.
